(19) United States
(12) Patent Application Publication
(10) Pub. No.: US 2025/0118603 A1
(43) Pub. Date: Apr. 10, 2025

(54) IMPROVED OPTICAL ACCESS FOR SPECTROSCOPIC MONITORING OF SEMICONDUCTOR PROCESSES

(71) Applicant: Verity Instruments, Inc., Carrollton, TX (US)

(72) Inventor: Mark Meloni, Carrollton, TX (US)

(21) Appl. No.: 18/729,439

(22) PCT Filed: Oct. 30, 2023
(86) PCT No.: PCT/US23/78189

§ 371 Date: Jul. 16, 2024

Related U.S. Application Data
(60) Provisional application No. 63/420,953, filed on Oct. 31, 2022.

(51) Int. Cl. H01L 21/66; H01J 37/32

(52) U.S. Cl. CPC H01L 22/12; H01J 37/3244; H01J 2237/2445; H01J 2237/24578

(57) ABSTRACT

The disclosure recognizes the advantage of improved optical access for spectroscopic monitoring of, for example, semiconductor processing. In one aspect the disclosure provides a gas distributor that can be used within a processing chamber. Unlike conventional gas distributors, the disclosed gas distributor includes one or more optically transmissive sections for improved optical access the chamber. In one example, the gas distributor includes: (1) an opaque section including a first set of gas distribution holes and (2) at least one optically transmissive section coupled to the opaque section and positioned to receive light through a window of the chamber.

### CROSS-REFERENCE TO RELATED APPLICATION

This application claims the benefit of U.S. Provisional Application Ser. No. 63/420,953 filed by Mark Meloni, on Oct. 31, 2022, entitled “Improved Optical Access for Spectroscopic Monitoring of Semiconductor Processes”, which is commonly assigned with this application and incorporated herein by reference in its entirety.

### TECHNICAL FIELD

This disclosure relates, generally, to optical spectroscopy systems and methods of use, and more specifically, to improved optical access for monitoring of optical signals during semiconductor processes from within semiconductor processing equipment.

### BACKGROUND

Optical monitoring of semiconductor processes is a well-established method for controlling processes such as etch, deposition, chemical mechanical polishing and implantation. Optical emission spectroscopy (OES) and interferometric endpoint (IEP) are two basic types of modes of operation for data collection. In OES applications light emitted from the process, typically from plasmas, is collected and analyzed to identify and track changes in atomic and molecular species which are indicative of the state or progression of the process being monitored. In IEP applications, light is typically supplied from an external source, such as a flashlamp, and directed onto a workpiece. Upon reflection from the workpiece, the sourced light carries information, in the form of the reflectance of the workpiece, which is indicative of the state of the workpiece. Extraction and modeling of the reflectance of the workpiece permits understanding of film thickness and feature sizes/depth/widths among other properties.

### BRIEF DESCRIPTION OF THE DRAWINGS

Reference is now made to the following descriptions taken in conjunction with the accompanying drawings, in which:

FIG. 1 is a block diagram of a system for employing OES and/or IEP to monitor and/or control the state of a plasma or non-plasma process within a semiconductor process tool that has a gas distributor, also referred to as a showerhead, constructed according to the principles of the disclosure;

FIG. 2 is a detail, in cross-section, of a portion of a gas distributor of a semiconductor processing tool including provisions from improved optical access, in accordance with this disclosure;

FIG. 3 is a schematic cross-section of various elements of a semiconductor processing system that interacts with optical signal transmission, in accordance with this disclosure;

FIG. 4 is a plot of the relative signal levels associated with optical transmission and reflection from various sub-elements of the schematic cross-section of FIG. 3, in accordance with this disclosure;

FIG. 5 illustrates a flow diagram of an example method of manufacturing a gas distributor carried out according to the principles of the disclosure; and

FIG. 6 illustrates a flow diagram of an example method of processing a workpiece using a gas distributor constructed according to the principles of the disclosure.

### DETAILED DESCRIPTION

In the following description, reference is made to the accompanying drawings that form a part hereof, and in which is shown by way of illustration, specific embodiments in which the disclosure may be practiced. These embodiments are described in sufficient detail to enable those skilled in the art to practice the disclosure, and it is to be understood that other embodiments may be utilized. It is also to be understood that structural, procedural and system changes may be made without departing from the spirit and scope of the present disclosure. The following description is, therefore, not to be taken in a limiting sense. For clarity of exposition, like features shown in the accompanying drawings are indicated with like reference numerals and similar features as shown in alternate embodiments in the drawings are indicated with similar reference numerals. Other features of the present disclosure will be apparent from the accompanying drawings and from the following detailed description. It is noted that, for purposes of illustrative clarity, certain elements in the drawings may not be drawn to scale.

The constant advance of semiconductor processes toward faster processes, smaller feature sizes, more complex structures, larger wafer, and more complex process chemistries places great demands on process monitoring technologies. For example, higher data rates are required to accurately monitor much faster etch rates on very thin layers where changes in Angstroms (a few atomic layers) are critical such as for fin field-effect transistor (FINFET) and three dimensional NAND (3D NAND) structures. Wider optical bandwidth and greater signal-to-noise are required in many cases both for OES and IEP methodologies to aid in detecting small changes either/both for reflectances and optical emissions.

Large wafer sizes with smaller overall component feature sizes and stringent requirements for within-wafer and wafer-to-wafer uniformity poses many constraints upon semiconductor processing equipment design. These constraints may limit the introduction of features which support optical monitoring access. For example, providing light to and obtaining reflected light from a workpiece in a processing chamber is an important aspect of optical monitoring. A gas distributor is one example of a component within a processing chamber that can affect optical monitoring.

A typical gas distributor is a metal or ceramic structure including an enclosed volume that has a multitude of small holes therein to support the uniform distribution of process gasses within a processing chamber. A gas plenum connected to a gas supply line can provide the gas for distribution. A gas distributor can be coupled to the sides of the processing chamber, suspended from a lid, or positioned another way as is common in the industry. The small holes of the gas distributor can range from approximately 0.1 mm to 2 mm in diameter and penetrate an exit plate with a thickness of multiple millimeters, wherein the resulting holes have a relatively high aspect ratio. Spacing of the holes may be on the order of 1 mm to 10 mm center-to-center with a resulting “open area” density of a few percent. The combination of low open area and high aspect ratio, which limits angular acceptance, are problematic for optical monitoring as the open area directly scales the signal levels and the high aspect ratio necessitates tight control over beam aiming and positioning. The resultant effective spot size for measurement may therefore be a single 1 mm diameter region for a 300 mm diameter wafer. This relates to characterizing the wafer using much less than 1%, e.g. ˜ 0.001% of the critical area of its surface. Working distances between optical interfaces of a processing chamber and a wafer being processed may range from less than 10 cm to greater than 1 m. As such the angular orientation and angular stability of components must often be less than fractions of single degrees to permit the transmission and reflection of monitoring optical signals. As processing chambers vary in temperature and pressure multiple components may shift position or angular orientations and inhibit the passage of optical signals rendering an optical monitoring system inoperable.

Accordingly, disclosed herein are adaptations to one or more components of semiconductor processing chambers that support improved optical access for spectroscopic monitoring. In one aspect the disclosure provides a gas distributor that can be used within a processing chamber. Unlike conventional gas distributors, the disclosed gas distributor includes one or more optically transmissive sections for improved optical access in a processing chamber. In addition to an optically transmissive section, the gas distributor includes an opaque section having holes for gas distribution, referred to herein as gas distribution holes.

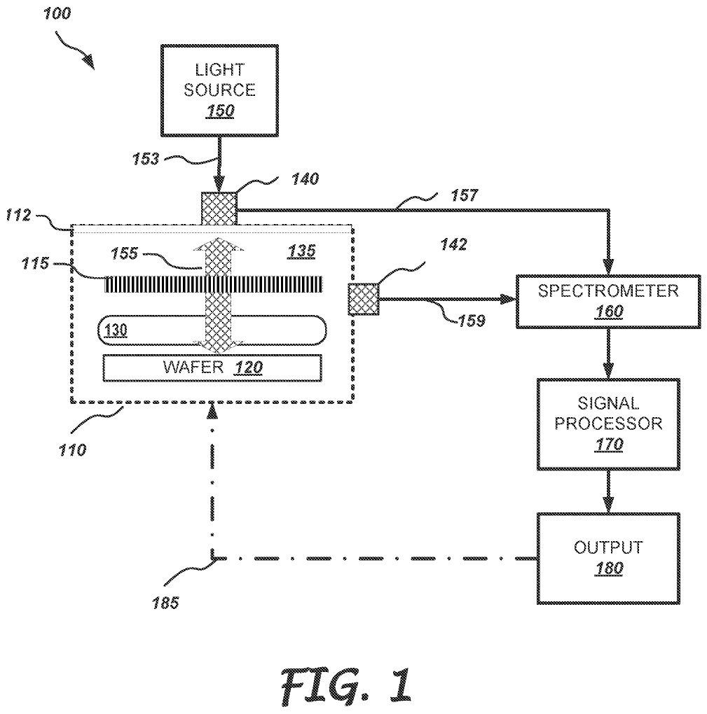

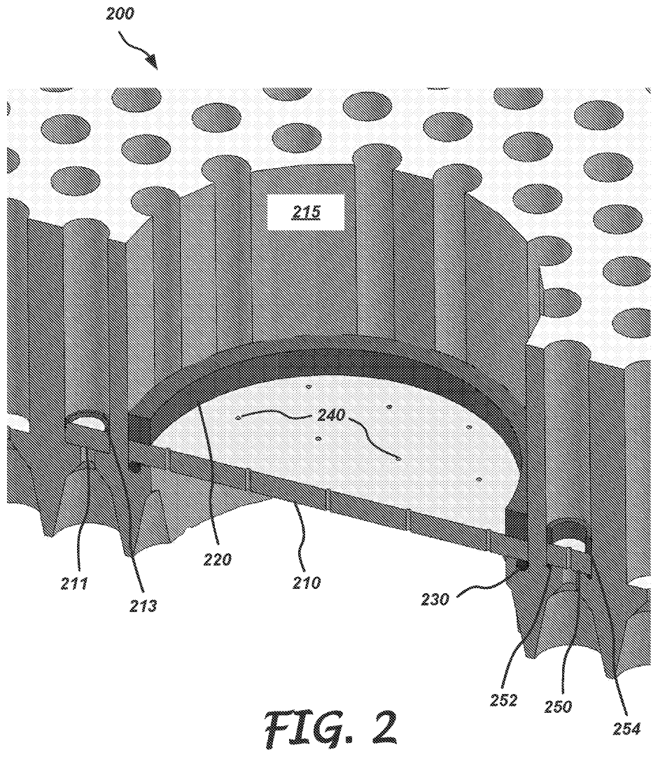

The dimensions of the optically transmissive sections can vary. For example, as illustrated in FIG. 2, an optically transmissive section (optically transmissive section 210) can fill an area of multiple gas distribution holes of an opaque section or can replace a single gas distribution hole (optically transmissive sections 211 and 250). As represented by optically transmissive sections 210 and 250, the one or more optically transmissive sections may also include at least one gas distribution hole, which can be a set of gas distribution holes. The set of gas distribution holes of the one or more optically transmissive sections and of the opaque section can have a same gas distribution rate. An optically transmissive section may not include a gas distribution hole, such as represented by optically transmissive section 211. The gas distributor can include multiple optically transmissive sections of the same size or of different sizes as shown in FIG. 2. FIG. 1 illustrates a process system that includes a processing chamber having a gas distributor as disclosed herein.

With specific regard to monitoring and evaluating the state of a semiconductor process within a process tool, FIG. 1 illustrates a block diagram of process system 100 utilizing OES and/or IEP to monitor and/or control the state of a plasma or non-plasma process within a semiconductor process tool 110. Semiconductor process tool 110, or simply process tool 110, generally encloses a workpiece, which is represented by wafer 120 in FIG. 1, and possibly process plasma 130 in a typically, partially evacuated volume of a processing chamber 135 that may include various process gases. Process tool 110 may include one or multiple optical interfaces, or simply interfaces, 140 and 142 to permit observation into the processing chamber 135 at various locations and orientations. Interfaces 140 and 142 may include multiple types of optical elements such as, but not limited to, optical filters, lenses, windows, apertures, fiber optics, etc.

For IEP applications, light source 150 may be connected with interface 140 directly or via fiber optical cable assembly 153. As shown in this configuration, interface 140 is oriented normal to the surface of wafer 120 and often centered with respect to the same. Light from light source 150 may enter the internal volume of processing chamber 135 in the form of collimated beam 155. Beam 155 upon reflection from the wafer 120 may again be received by interface 140. In common applications, interface 140 may be an optical collimator. Following receipt by interface 140, the light may be transferred via fiber optic cable assembly 157 to spectrometer 160 for detection and conversion to digital signals. The light can include sourced and detected light and may include, for example, the wavelength range from deep ultraviolet (DUV) to near-infrared (NIR). Wavelengths of interest may be selected from any subrange of the wavelength range. For larger substrates or where understanding of wafer non-uniformity is a concern, additional optical interfaces (not shown in FIG. 1) normally oriented with the wafer 120, such as optical interface 140, may be used. The additional optical interfaces may be optically coupled to light source 150 or may be associated with additional light sources. The processing tool 110 can also include additional optical interfaces positioned at different locations, such as optical interface 142, for other monitoring options.

Of particular interest for IEP applications are chamber components which interfere with the transmission and reflection of collimated beam 155. Specifically, chamber lid 112 may strongly interact with collimated beam 155 to degrade the application of optical monitoring of wafer 120 in the processing chamber 135. Chamber lid 112 is primarily a mechanical component which supports the enclosing of processing chamber 135 allowing the containment of processing chemicals and any process plasma. To support optical monitoring chamber lid 112 may include some portion that is optically transparent or translucent. Typically, this portion is an independent component, namely a window or viewport, but in certain applications where the chamber lid 112 is made of quartz, a viewport may be created from a polished portion of the unified lid.

A gas distributor can also cause interference with the transmission and reflection of collimated beam 155. However, process system 100 includes gas distributor 115 that provides the primary function of uniformly distributing process gasses across the surface of wafer 120 and at least reduces optical interference. As such, instead of a conventional gas distributor, gas distributor 115 includes at least one optically transmissive section in addition to an opaque section of a typical gas distributor. As with the opaque section, the optically transmissive section or sections can include a set of gas distribution holes, such as represented by gas distributor 200 of FIG. 2. The gas distributor 115 can include a combination of optically transmissive sections with gas distribution holes and without gas distribution holes. As noted above with respect to a conventional gas distributor, the gas distribution holes can be small holes having a diameter range of 0.1 mm to 2 mm, have a relatively high aspect ratio, and be spaced on the order of 1 mm to 10 mm center to center.

For OES applications, interface 142 may be oriented to collect light emissions from plasma 130. Interface 142 may simply be a viewport or may additionally include other optics such as lenses, mirrors, and optical wavelength filters. Fiber optic cable assembly 159 may direct any collected light to spectrometer 160 for detection and conversion to digital signals. The spectrometer 160 can include a CCD sensor and convertor for the detection and conversion. Multiple interfaces may be used separately or in parallel to collect OES related optical signals.

In many semiconductor processing applications, it is common to collect both OES and IEP optical signals and this collection provides multiple problems for using spectrometer 160. Typically OES signals are continuous in time whereas IEP signals may be either/both continuous or discrete in time. The mixing of these signals causes numerous difficulties as process control often requires the detection of small changes in both the OES and IEP signals and the inherent variation in either signal can mask the observation of the changes in the other signal. It is not advantageous to support multiple spectrometers for each signal type due to, for example, cost, complexity, inconvenience of signal timing synchronization, calibration and packaging.

After detection and conversion of the received optical signals to analog electrical signals by the spectrometer 160, the analog electrical signals are typically amplified and digitized within a subsystem of spectrometer 160, and passed to signal processor 170. Signal processor 170 may be, for example, an industrial PC, PLC or other system, which employs one or more algorithms to produce output 180 such as, for example, an analog or digital control value representing the intensity of a specific wavelength or the ratio of two wavelength bands. Instead of a separate device, signal processor 170 may alternatively be integrated with spectrometer 160. The signal processor 170 may employ an OES algorithm that analyzes emission intensity signals at predetermined wavelength(s) and determines trend parameters that relate to the state of the process and can be used to access that state, for instance end point detection, etch depth, etc. For IEP applications, the signal processor 170 may employ an algorithm that analyzes wide-bandwidth portions of spectra to determine a film thickness. For example, see System and Method for In-situ Monitor and Control of Film Thickness and Trench Depth, U.S. Pat. No. 7,049,156, incorporated herein by reference. Output 180 may be transferred to process tool 110 via communication link 185 for monitoring and/or modifying the production process occurring within chamber 135 of the process tool 110.

The shown and described components of FIG. 1 are simplified for expedience and are commonly known. As noted above, instead of a conventional gas distributor, gas distributor 115 is used that includes at least one optically transmissive section, such as gas distributor 200 or gas distributor 350. In addition to common functions, the spectrometer 160 or the signal processor 170 can also be configured to identify stationary and transient optical and non-optical signals and process these signals according to the methods and/or features disclosed herein. As such, the spectrometer 160 or the signal processor 170 can include algorithms, processing capability, and/or logic to identify and process optical signals and temporal trends extracted therefrom. The algorithms, processing capability, and/or logic can be in the form of hardware, software, firmware, or any combination thereof. The algorithms, processing capability, and/or logic can be within one computing device or can also be distributed over multiple devices, such as the spectrometer 160 and the signal processor 170.

FIG. 2 shows a detail, in cross-section, of a portion of a gas distributor 200 of a semiconductor processing tool including provisions for improved optical access according to the principles of the disclosure. Unlike a conventional gas distributor, gas distributor 200 includes modified regions designed and fabricated to support the inclusion of optically transmissive sections, also referred to as transparent components. Optically transmissive section 210 may be for example a sapphire or fused silica disk with a diameter ranging from approximately 0.25″ to 1″ and a thickness ranging from approximately 0.04″ to 0.25″. Optically transmissive section 210 mates with a feature of gas distributor 200 to retain it, such as a non-transparent component, also referred to as opaque section 215 of gas distributor 200. As shown in FIG. 2, the mating feature can be an appropriately sized hole where material has been removed from the opaque section 215 or constructed within the opaque section 215 of the gas distributor 200. Thus, gas distributor 200 can be manufactured by modifying an already constructed, approved gas distributor to add optically transmissive section 210 (and optically transmissive sections 211 and 250) or originally manufactured with an opening (or openings) for the one or more optically transmissive sections.

Optically transmissive section 210 may be retained by a retainer, such as retaining ring 220 which may be a threaded or snap-ring mechanism. Optically transmissive section 210 may also be sealed to other portions of the gas distributor 200 via a seal, such as o-ring 230. Optically transmissive section 210 may include multiple holes of an appropriate size, pitch, and cross-section to support approximate gas flow characteristics to those within the opaque section 215 of the gas distributor 200. For example, the opaque section 215 can include a first set of gas distribution holes, such as described above with respect to gas distributor 115, and the optically transmissive section 210, coupled to the opaque section 215, can include a second set of gas distribution holes, wherein the second set of gas distribution holes provides a same gas distribution and flow rate as the first set of gas distribution holes. Although FIG. 2 shows removal of essentially all of the original material above and below optically transmissive section 210, portions of gas distributor 200 may be retained to support required mechanical mounting or other requirements. Specifically, in an example where gas distributor 200 is metallic or conductive the portion of the gas distributor 200 nearest the process plasma (the exit nozzle or “bottom” side in FIG. 2) may be retained to ensure plasma uniformity.

Optically transmissive section 210 may generally be considered a “window” if parallel planar surfaces are used for the component. Otherwise, the optically transmissive section 210 may be a non-planar optical element providing additional modification or benefits to the optical signal. Compared to the optical access provided by one or more holes in the generally opaque section 215, the inclusion of optically transmissive section 210 provides essentially uninhibited optical access across the diameter thereof. As noted above, the gas distributor 200 can include more than one optically transmissive section 210. The number, size, and positioning of multiple optically transmissive sections can be subject to any requirements for optical access for monitoring. Optically transmissive sections 211 and 250, represent additional optically transmissive sections for additional optical access.

As represented by optically transmissive sections 211 and 250, gas distributor 200 can include one or more additional optically transmissive sections that have a smaller diameter compared to the diameter of optically transmissive section 210, which can minimize the perturbation of the process conditions in the modified or open region of the opaque section 215 relative to unmodified regions of the opaque section 215. Optically transmissive sections 211 and 250 replace individual gas distribution holes in section 215 but gas distributor 200 can also include other optically transmissive sections having different diameters and positioned at different locations. Portions of exit nozzles for the optically transmissive sections may be retained subject to limitations posed upon optical access due to non-optically transmitting portions thereof. The gas distributor 200 can include optically transmissive sections that are positioned between gas distribution holes of the opaque section 215 and these positioned optically transmissive sections may not include gas distribution holes.

The optically transmissive sections may or may not include one or more gas distribution holes. For example, optically transmissive section 211 does not include a gas distribution hole and optically transmissive section 250 includes a distribution hole. Similar to optically transmissive section 210, optically transmissive section 250 also includes an o-ring 252 and a retainer 254. An optically transmissive section can also be coupled to the opaque section 215 using a bonding agent, such as represented by the bond 213 used to secure optically transmissive section 211. The bonding agent can also be used to seal the coupling. The bonding agent can be a conventional epoxy, glue, material, etc. used in the industry. The bonding agent can differ depending on the material of the opaque section 215 and of the optically transmissive sections. As represented by the different optically transmissive sections of FIG. 2, any combination of the size, location, gas distribution hole or not, a number of gas distribution holes, and coupling means can vary.

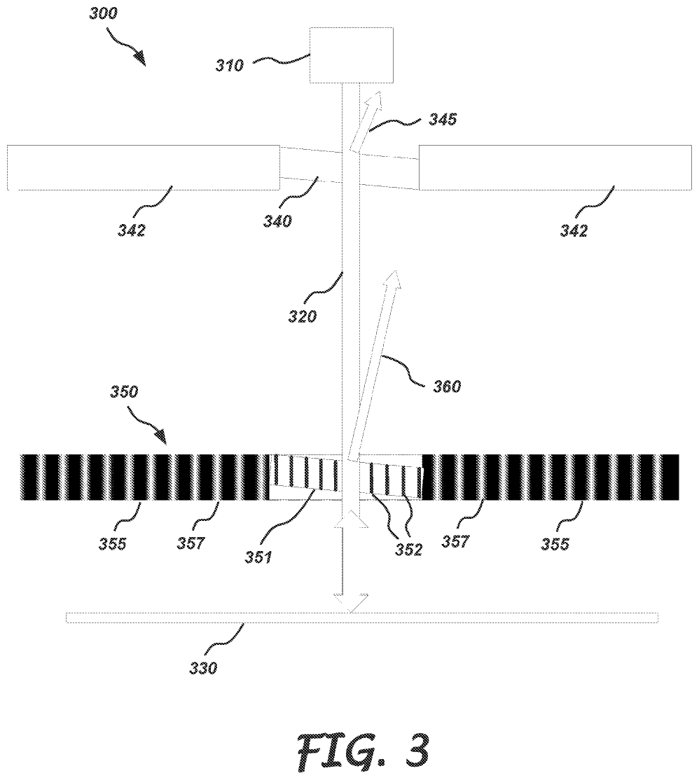

FIG. 3 is a schematic cross-section of various elements of a semiconductor processing system 300, which interact with optical signal transmission. The various components can be located within or proximate a processing chamber, such a processing chamber 135 of FIG. 1. For example, components 140, 112, and 115 of FIG. 1 can be components 310, 342, and 350 of FIG. 3. Optical interface 310, e.g. an optical collimator, provides an optical signal 320 that is used to characterize a portion of wafer 330. Optical signal 320 may first interact and be partially reflected from a window or viewport 340 within a chamber lid 342 whereby forming scattered beam 345. Window 340 may be inclined with respect to the optical axis of optical interface 310 so that scattered beam 345 is not recollected by optical interface 310 since it does not include information regarding wafer 330. Optical signal 320 may also interact and scatter from an optically transmissive section optically transmissive section 351, which is part of gas distributor 350, whereby forming scattered beam 360. Optically transmissive section 351 may also be inclined with respect to the optical axis of optical interface 310 to avoid recollection of scattered beam 360. Three to five degrees or more inclination may be used.

Holes for the flow of gasses through optically transmissive section 351 are represented by gas distribution holes 352. Hole spacing, sizes, etc. may be as described according to optically transmissive section 210 of FIG. 2. Furthermore, when optically transmissive section 351 is inclined, the gas distribution holes 352 may be non-normal to the surfaces of optically transmissive section 351 such that gas flow trajectories exiting optically transmissive section 351 are in accord with trajectories through gas distribution holes 357 of the opaque section 355 of the gas distributor 350. As such, centerlines through vertical axes of the gas distribution holes 352 of the optically transmissive section 351 and the gas distribution holes 357 of the opaque section 355 are parallel. A retainer and seal for the optically transmissive section 351 are also not shown in FIG. 3 but can be used as described in FIG. 2 with modifications due to the inclination of optically transmissive section 351 with respect to the opaque section 355 of gas distributor 350.

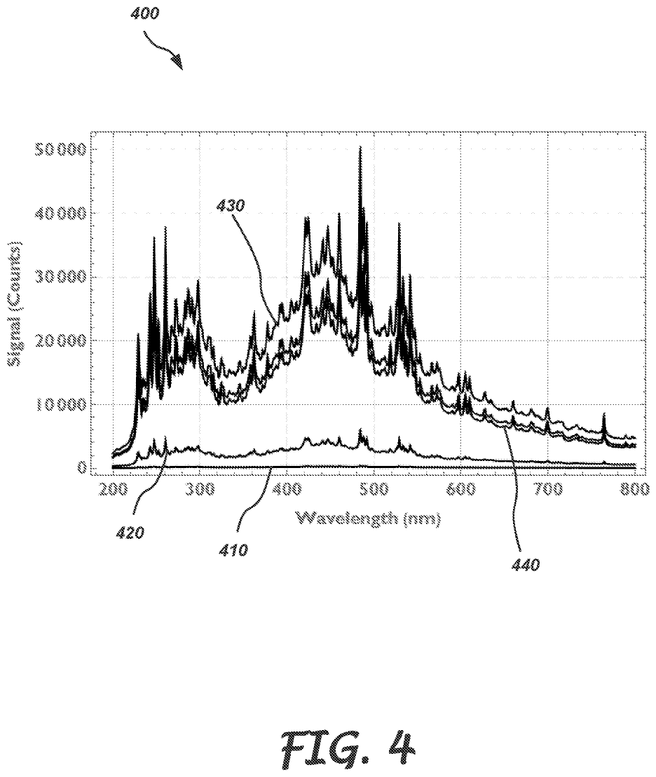

FIG. 4 is a plot 400 of the signal levels associated with optical transmission and reflection from various sub-elements of the schematic cross-section of FIG. 3. Plot 400 has an x axis in wavelength units and a y axis of signal count units. Spectrum 410 represents the useful optical signal recollected when an unmodified or conventional gas distributor is utilized and the optical signal is severely limited by the small holes in the gas distributor. Spectrum 420 represents the optical signals that may arise from the re-collection of undesirable reflections from surfaces other than that of the wafer. Spectrum 430 represents the original source signal level. Spectrum 440 represents the useful re-collected signal level including the losses according to spectrum 420 when a gas distributor including a transparent component as disclosed herein is used.

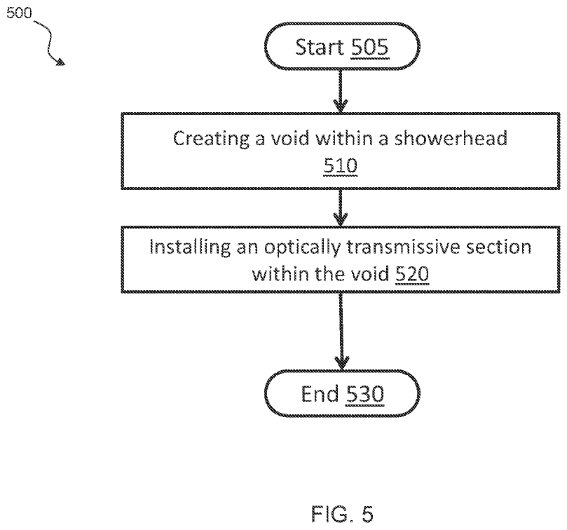

FIG. 5 illustrates a flow diagram of an example method 500 of manufacturing a gas distributor carried out according to the principles of the disclosure. The manufactured gas distributor can be, for example, any of the gas distributors disclosed herein that include at least one optically transmissive section. The method 500 can be repeated for multiple optically transmissive sections. Method 500 can be used with one or more optically transmissive sections. The method 500 begins in step 505.

In step 510, a void is created within a gas distributor. The void can be created by drilling a hole in a gas distributor, or more specifically, an opaque section of a gas distributor. The opaque section can be designed with gas distribution holes to provide a desired distribution and flow rate. Accordingly, the opaque section can be approved for operation. The opaque section can be constructed of aluminum or another metal depending, for example, on the application in which the gas distributor will be used (e.g., the gases that will be present in the process chamber).

The void can also be manufactured when constructing the opaque section. For example, the opaque section can be constructed of a ceramic and the void can be created when forming the ceramic for the opaque section. Regardless the material, multiple voids can be created when more than one optically transmissive section is used.

In step 520 an optically transmissive section is installed within the void. The optically transmissive section can be placed in the void at an angle or inclination such as noted in FIG. 3. A retainer and seal can be used when installing the optically transmissive section within the void. The seal can be thicker or wider on one side to compensate for the inclination when present. One or more retainer can be used to secure the optically transmissive section within void of the opaque section. The void can also be formed with a lip to assist in holding the optically transmissive section in place and, when present, the proper inclination. A bonding agent can also be used to seal and secure the optically transmissive section within the void. The method 500 ends in step 530.

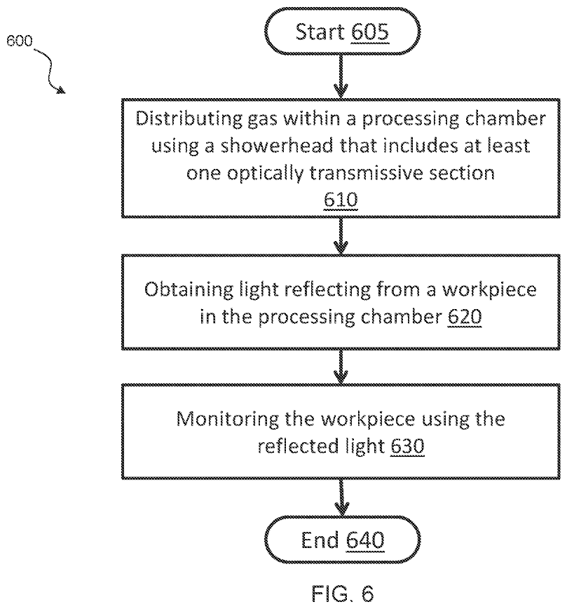

FIG. 6 illustrates a flow diagram of an example method 600 of processing a workpiece using a gas distributor constructed according to the principles of the disclosure. The method 600 can take place within a processing chamber, such as processing chamber 135 of FIG. 1. The method 600 is an IEP monitoring method. Additional steps may be included with the method 600, such as providing light on the workpiece from an external light source, such as external light source 150. The method 600 begins in step 605.

In step 610, gas is distributed in a processing chamber using a gas distributor that includes at least one optically transmissive section. One of the multiple gas distributors disclosed herein can be used.

In step 620, light that is reflected from a workpiece in the processing chamber is obtained. The reflected light can be obtained via an optical interface, such as optical interface 140, via the at least one optically transmissive section and sent to a spectrometer. The reflected light can be sent via a fiber optic cable assembly, such as fiber optic cable assembly 157 of FIG. 1.

In step 630, processing of the workpiece is monitored using the reflected light. The spectrometer can be used for the monitoring. The method 600 continues to step 640 and ends. The method 600 can be repeated multiple times during processing of the workpiece in the processing chamber. The workpiece can be, for example, a wafer such as wafer 120.

The changes described above, and others, may be made in the optical measurement systems and subsystems described herein without departing from the scope hereof. For example, although certain examples are described in association with semiconductor wafer processing equipment, it may be understood that the optical measurement systems described herein may be adapted to other types of processing equipment such as roll-to-roll thin film processing, solar cell fabrication or any application where high precision optical measurement may be required. Furthermore, although certain embodiments discussed herein describe the use of a common light analyzing device, such as an imaging spectrograph, it should be understood that multiple light analyzing devices with known relative sensitivity may be utilized. Furthermore, although the term “wafer” has been used herein when describing aspects of the current disclosure, it should be understood that other types of workpieces such as quartz plates, phase shift masks, LED substrates and other non-semiconductor processing related substrates and workpieces including solid, gaseous and liquid workpieces may be used.

The embodiments described herein were selected and described in order to best explain the principles of the disclosure and the practical application, and to enable others of ordinary skill in the art to understand the disclosure for various embodiments with various modifications as are suited to the particular use contemplated. The particular embodiments described herein are in no way intended to limit the scope of the present disclosure as it may be practiced in a variety of variations and environments without departing from the scope and intent of the disclosure. Thus, the present disclosure is not intended to be limited to the embodiments shown, but is to be accorded the widest scope consistent with the principles and features described herein.

The flowchart and block diagrams in the figures illustrate the architecture, functionality, and operation of possible implementations of systems, methods and computer program products according to various embodiments of the present disclosure. In this regard, each block in the flowchart or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems which perform the specified functions or acts, or combinations of special purpose hardware and computer instructions.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one of skill in the art, portions disclosed herein may be embodied as a method, system, or computer program product. Accordingly, disclosed portions may take the form of an entirely hardware embodiment, an entirely software embodiment (including firmware, resident software, micro-code, etc.) or an embodiment combining software and hardware aspects all generally referred to herein as a “circuit” or “module.” Configured or configured to means, for example, designed, constructed, or programmed, with the necessary logic, algorithms, processing instructions, and/or features for performing a task or tasks.

Various aspects of the disclosure can be claimed including the apparatuses, systems, and methods disclosed herein. Aspects disclosed herein include:
A. A gas distributor for semiconductor processing in a chamber, including: (1) an opaque section including a first set of gas distribution holes; and (2) at least one optically transmissive section coupled to the opaque section and positioned to receive light through a window of the chamber.
B. A processing chamber, including; (1) a lid having a window and (2) a gas distributor having an opaque section including a first set of gas distribution holes and at least one optically transmissive section coupled to the opaque section and aligned with the window to receive light.
C. A method of making a gas distributor for a processing chamber, including: (1) creating a void within a gas distributor and (2) installing an optically transmissive section within the void.
D. A method of processing a workpiece employing a processing chamber, including: (1) distributing gas in a processing chamber using a gas distributor having at least one optically transmissive section, (2) obtaining, via the at least one optically transmissive section, light reflected from a workpiece located in the processing chamber, and (3) monitoring interaction of the gas with workpiece using the reflected light.

Each of aspects A, B, C, and D can have one or more of the following additional elements in combination: Element 1: wherein the gas distributor has multiple optically transmissive sections coupled to the opaque section that are positioned within the opaque section to receive the light. Element 2: wherein the at least one optically transmissive section includes a second set of gas distribution holes, wherein the second set of gas distribution holes provides a same gas distribution and flow rate as the first set of gas distribution holes. Element 3: wherein a longitudinal axis of the at least one optically transmissive section is non-parallel with a longitudinal axis of the opaque section. Element 4: wherein the longitudinal axis of the at least one optically transmissive section is tilted in a range of three to five degrees compared to the longitudinal axis of the opaque section. Element 5: wherein the second set of gas distribution holes are parallel to the first set of gas distribution holes. Element 6: further comprising a seal located between a portion of the at least one optically transmissive section and the opaque section. Element 7: further comprising a retainer that secures the at least one optically transmissive section with the opaque section. Element 8: wherein the at least one optically transmissive section is constructed of sapphire. Element 9: wherein the at least one optically transmissive section is constructed of fused silica. Element 10: wherein the at least one optically transmissive section is a prism with a diameter ranging from approximately 0.25″ to 1″ and a thickness ranging from approximately 0.04″ to 0.25″. Element 11: wherein a diameter of at least one of the second set of gas distribution holes is different than a diameter of at least one of the first set of gas distribution holes. Element 12: comprising multiple optically transmissive sections that each have a set of gas distribution holes that provides a same gas distribution and flow rate as the first set of gas distribution holes. Element 13: wherein the gas distributor has multiple optically transmissive sections coupled to the opaque section that are positioned within the opaque section to receive the light via the window. Element 14: wherein the at least one optically transmissive section includes a second set of gas distribution holes, wherein the second set of gas distribution holes provides a same gas distribution and flow rate as the first set of gas distribution holes. Element 15: wherein the second set of gas distribution holes are parallel to the first set of gas distribution holes. Element 16: wherein a longitudinal axis of the at least one optically transmissive section is non-parallel with a longitudinal axis of the opaque section. Element 17: wherein the at least one optically transmissive section is coupled to the opaque section via a bonding agent. Element 18: wherein the installing includes securing and sealing the optically transmissive section within the void. Element 19: wherein the installing includes placing the optically transmissive section at an angle with respect to a longitudinal axis of the gas distributor.

1. A gas distributor for semiconductor processing in a chamber, comprising:
an opaque section including a first set of gas distribution holes; and
at least one optically transmissive section coupled to the opaque section and positioned to receive light through a window of the chamber.

2. The gas distributor as recited in claim 1, wherein the gas distributor has multiple optically transmissive sections coupled to the opaque section that are positioned within the opaque section to receive the light.

3. The gas distributor as recited in claim 1, wherein the at least one optically transmissive section includes a second set of gas distribution holes, wherein the second set of gas distribution holes provides a same gas distribution and flow rate as the first set of gas distribution holes.

4. The gas distributor as recited in claim 3, wherein a longitudinal axis of the at least one optically transmissive section is non-parallel with a longitudinal axis of the opaque section.

5. The gas distributor as recited in claim 4, wherein the longitudinal axis of the at least one optically transmissive section is tilted in a range of three to five degrees compared to the longitudinal axis of the opaque section.

6. The gas distributor as recited in claim 1, wherein the second set of gas distribution holes are parallel to the first set of gas distribution holes.

7. The gas distributor as recited in claim 1, further comprising a seal located between a portion of the at least one optically transmissive section and the opaque section.

8. The gas distributor as recited in claim 1, further comprising a retainer that secures the at least one optically transmissive section with the opaque section.

9. The gas distributor as recited in claim 1, wherein the at least one optically transmissive section is constructed of sapphire.

10. The gas distributor as recited in claim 1, wherein the at least one optically transmissive section is constructed of fused silica.

11. The gas distributor as recited in claim 1, wherein the at least one optically transmissive section is a prism with a diameter ranging from approximately 0.25″ to 1″ and a thickness ranging from approximately 0.04″ to 0.25″.

12. The gas distributor as recited in claim 1, wherein a diameter of at least one of the second set of gas distribution holes is different than a diameter of at least one of the first set of gas distribution holes.

13. The gas distributor as recited in claim 1, comprising multiple optically transmissive sections that each have a set of gas distribution holes that provides a same gas distribution and flow rate as the first set of gas distribution holes.

14. A processing chamber, comprising;
a lid having a window; and
a gas distributor including:
an opaque section including a first set of gas distribution holes; and
at least one optically transmissive section coupled to the opaque section and aligned with the window to receive light.

15. The processing chamber as recited in claim 14, wherein the gas distributor has multiple optically transmissive sections coupled to the opaque section that are positioned within the opaque section to receive the light via the window.

16. The processing chamber as recited in claim 14, wherein the at least one optically transmissive section includes a second set of gas distribution holes, wherein the second set of gas distribution holes provides a same gas distribution and flow rate as the first set of gas distribution holes.

17. The processing chamber as recited in claim 16, wherein the second set of gas distribution holes are parallel to the first set of gas distribution holes.

18. The processing chamber as recited in claim 14, wherein a longitudinal axis of the at least one optically transmissive section is non-parallel with a longitudinal axis of the opaque section.

19. The processing chamber as recited in claim 14, wherein the at least one optically transmissive section is coupled to the opaque section via a bonding agent.

20. A method of making a gas distributor for a processing chamber, comprising:
creating a void within a gas distributor; and
installing an optically transmissive section within the void.

21. The method as recited in claim 20, wherein the installing includes securing and sealing the optically transmissive section within the void.

22. The method as recited in claim 20, wherein the installing includes placing the optically transmissive section at an angle with respect to a longitudinal axis of the gas distributor.

23. A method of processing a workpiece employing a processing chamber, comprising:
distributing gas in a processing chamber using a gas distributor having at least one optically transmissive section;
obtaining, via the at least one optically transmissive section, light reflected from a workpiece located in the processing chamber; and
monitoring interaction of the gas with workpiece using the reflected light.
